(19) United States
(12) Patent Application Publication
(10) Pub. No.: US 2026/0188627 A1
(43) Pub. Date: Jul. 2, 2026

(54) JIG DEVICE AND METHOD OF MOUNTING FOCUS RING USING THE SAME

(71) Applicant: SEMES CO., LTD., Cheonan-si (KR)

(72) Inventors: Hyung Kwan CHANG, Cheonan-si (KR); Jin Hyun LEE, Cheonan-si (KR); Chun Loon CHA, Cheonan-si (KR)

(73) Assignee: SEMES CO., LTD., Cheonan-si (KR)

(21) Appl. No.: 19/437,550

(22) Filed: Dec. 31, 2025

(30) Foreign Application Priority Data
Dec. 31, 2024 (KR) 10-2024-0203045
Mar. 6, 2025 (KR) 10-2025-0028656

(51) Int. Cl. H01J 37/32

(52) U.S. Cl. CPC H01J 37/32642; H01J 2237/1502

(57) ABSTRACT

Disclosed are a jig device and a method of mounting a focus ring using the jig device, wherein the jig device is configured to align the position of a consumable component on a substrate processing device and to support mounting of the consumable component on the substrate processing device, and the focus ring is mounted on a substrate support unit by the method using the jig device.

### CROSS-REFERENCE TO THE RELATED APPLICATION

The present application claims priority to and the benefit of Korean Patent Application No. 10-2025-0028656, filed on March 6, 2025 and Korean Patent Application No. 10-2024-0203045, filed on December 31, 2024, in the Korean Intellectual Property Office, the entire disclosure of each of which is incorporated herein by reference.

### BACKGROUND

### 1. Field

The present disclosure relates to a jig device and a method of mounting a focus ring using the jig device, and more particularly, to a jig device configured to support mounting of a consumable component on a substrate processing device by aligning the position of the consumable component on the substrate processing device and a method of mounting a focus ring on a substrate support unit using the jig device.

### 2. Description of the Related Art

A plasma method is generally used to perform a process such as etching an object to be processed such as a semiconductor wafer.

A substrate processing device that performs a plasma process arranges a substrate support unit such as an electrostatic chuck in a process space of a process chamber and places a substrate on the substrate support unit, thereby performing the plasma process.

The substrate processing device has a plurality of consumable components mounted thereto, and consumable components need to be periodically replaced depending on the processing execution time. These consumable components are required to be mounted at the appropriate positions of the substrate processing device. If these consumable components are mounted on the substrate processing device in a state in which the consumable components are not appropriately aligned, required performance may not be achieved.

For example, in order to focus plasma on a substrate to be processed and maintain plasma uniformity, the substrate support unit has a focus ring mounted thereon and disposed to surround the outer periphery of the substrate. The focus ring may be fixedly mounted on the substrate support unit with an adhesive pad interposed therebetween.

Here, the center position of the focus ring on the substrate support unit needs to be adjusted to maintain symmetry of the focus ring when the focus ring is mounted on the substrate support unit. In this case, when the focus ring having the adhesive pad attached thereto is mounted on the substrate support unit, position adjustment of the focus ring may not be appropriately performed.

Therefore, there is demand for a method of appropriately adjusting the center position of the focus ring when the focus ring is mounted on the substrate support unit.

### SUMMARY

Therefore, the present disclosure has been made in view of the above problems, and it is an object of the present disclosure to propose a method of aligning, when various consumable components are mounted on a substrate processing device, the positions of the consumable components for stable mounting of the consumable components on the substrate processing device.

It is another object of the present disclosure to solve a problem related to difficulty in adjusting the center position of a focus ring when the focus ring having an adhesive pad attached thereto is mounted on a substrate support unit.

The objects of the present disclosure are not limited to the above-mentioned objects, and other technical objects not mentioned herein will be clearly understood by those skilled in the art to which the present disclosure pertains from the detailed description of the embodiments.

In accordance with an aspect of the present disclosure, the above and other aspects can be accomplished by the provision of a jig device including a jig plate fixed to a substrate processing device configured for a consumable component to be mounted thereon, a jig body having an annular shape and providing a component mounting space corresponding to a component mounting portion of the substrate processing device, the jig body being rotatable in a state of being supported by the jig plate, and a jig member supported by the jig plate, wherein the jig member is moved by rotation of the jig body such that a support portion of the jig member is exposed to the component mounting space to support the consumable component to be mounted.

The jig body may have a mode switching track provided therein and configured to, based on the rotation of the jig body, move the jig member so as to allow the support portion of the jig member to be selectively exposed to the component mounting space, the mode switching track may be provided in plural, the mode switching tracks may be spaced apart from each other with an equal interval therebetween in a circumferential direction of the jig body, the jig member may be provided in plural corresponding to the plurality of mode switching tracks, and the jig members may be spaced apart from each other with an equal interval therebetween in the circumferential direction.

The support portions of the plurality of jig members may be simultaneously exposed to the component mounting space when the jig body is rotated in one direction, thereby enabling the jig device to be switched to a support mode in which the consumable component to be mounted is supported by the plurality of support portions, and the support portions of the plurality of jig members may be simultaneously inserted into an inner side of the jig body when the jig body is rotated in the other direction, thereby enabling the jig device to be switched to a mounting mode in which the consumable component to be mounted is mounted on and supported by the component mounting portion of the substrate processing device.

The jig body may include an upper cover having the plurality of mode switching tracks provided therein and spaced apart from each other in the circumferential direction, and a lower cover coupled to a lower portion of the upper cover, the lower cover providing a jig plate mounting space configured for the jig plate to be positioned therein.

Each of the mode switching tracks may include a mode switching hole line or a mode switching groove line, the mode switching hole line being formed to pass through the upper cover in a diagonal direction of the circumferential direction of the upper cover, the mode switching groove line being formed to be recessed in the upper cover, and the jig member may include a mode switching protrusion coupled to the mode switching track and configured to be moved along the mode switching track.

A length of the mode switching track may be divided into a radial length element and a circumferential length element, wherein the radial length element corresponds to a length of the support portion of the jig member exposed to the component mounting space, and wherein the circumferential length element corresponds to a movement speed of the jig member in a radial direction.

The jig body may include a damper space formed to be open by a length corresponding to the circumferential length element of the mode switching track, and the jig plate may include a damper block positioned in the damper space, the damper block being configured to, based on the rotation of the jig body, contact partition walls on opposite sides of the damper space to limit a rotation angle of the jig body.

The jig body may have the mode switching tracks and the damper spaces provided therein and alternately arranged in the circumferential direction.

The jig plate may include a jig member mounting groove configured for the jig member to be mounted thereon, the jig member mounting groove being configured to, based on movement of the jig member by the rotation of the jig body, guide radial movement of the jig member.

The jig member may further include a guide protrusion protruding downwards, and the jig plate may further include a guide line radially formed as a guide groove line or a guide hole line in the jig member mounting groove and configured for the guide protrusion to be coupled thereto, the guide line being configured to guide the radial movement of the jig member and to prevent separation of the jig member.

The jig member may include a seating guide surface formed to be inclined at an end portion of the support portion to guide seating of the consumable component to be mounted on the component mounting portion of the substrate processing device.

The jig device may further include a fixing tab coupled to the substrate processing device to fix the jig plate, and the jig plate may include a tab coupling portion configured for the fixing tab to be coupled thereto.

The jig device may further include a handle connected to the jig body and configured to rotate the jig body through external force applied to the handle.

In accordance with another aspect of the present disclosure, there is provided a method of mounting a focus ring using a jig device, the method including a support mode switching step of exposing a jig member of the jig device mounted on a substrate support unit to a component mounting space according to rotation of a jig body in one direction, a focus ring support step of spacing, by the jig member, a focus ring having an adhesive pad attached thereto from a focus ring mounting portion of the substrate support unit and supporting, by the jig member, the focus ring in the component mounting space, a focus ring position adjustment step of adjusting a position of the focus ring in a state in which the jig member constantly supports the focus ring, and a mounting mode switching step of releasing, based on the jig member being gradually inserted into an inner side of the jig body according to rotation of the jig body in the other direction, support of the jig member for the focus ring, and then allowing the focus ring to be seated on the focus ring mounting portion of the substrate support unit.

The support mode switching step may include radially moving, based on rotation of the jig body in one direction in a state in which the jig body is supported by a jig plate of the jig device fixed to the substrate support unit, the jig member by a radial length element of a mode switching track provided in the jig body, and then allowing a support portion of the jig member to be exposed to the component mounting space.

The focus ring support step may include supporting, by a support portion of the jig member, an outer portion of the focus ring, wherein the adhesive pad is not attached to the outer portion.

The focus ring position adjustment step may include adjusting, by a gap adjustment film, the position of the focus ring, the gap adjustment film being inserted between a side surface of the focus ring and a side surface of the substrate support unit.

The mounting mode switching step may include radially moving, based on the rotation of the jig body in the other direction in a state in which the jig body is supported by a jig plate of the jig device fixed to the substrate support unit, the jig member by a radial length element of a mode switching track provided in the jig body, and then allowing the jig member to be gradually inserted into the inner side of the jig body.

The mounting mode switching step may include controlling a radial movement speed of the jig member by a circumferential length element of the mode switching track provided in the jig body.

In accordance with a further aspect of the present disclosure, there is provided a jig device including a jig plate fixed to a substrate processing device configured for a consumable component to be mounted thereon, a jig body having an annular shape and providing a component mounting space corresponding to a component mounting portion of the substrate processing device, the jig body including an upper cover and a lower cover, the upper cover having a plurality of mode switching tracks provided therein and spaced apart from each other in a circumferential direction, the lower cover coupled to a lower portion of the upper cover and configured to provide a jig plate mounting space configured for the jig plate to be positioned therein, the jig body being rotatable in a state of being supported by the jig plate, and a plurality of jig members supported by the jig plate, each of the jig members including a mode switching protrusion coupled to the mode switching track, wherein the jig members are moved by rotation of the jig body such that support portions of the jig members are exposed to the component mounting space to support the consumable component to be mounted, and wherein the plurality of jig members are provided corresponding to the plurality of mode switching tracks, wherein each of the mode switching tracks includes a mode switching hole line or a mode switching groove line, the mode switching hole line being formed to pass through the upper cover in a diagonal direction of the circumferential direction of the upper cover, the mode switching groove line being formed to be recessed in the upper cover, and is configured to, based on the rotation of the jig body, move a corresponding one of the jig members so as to allow the support portion of the corresponding one of the jig members to be selectively exposed to the component mounting space, wherein a length of each of the mode switching tracks is divided into a radial length element and a circumferential length element, the radial length element corresponding to a length of the support portion of the jig member exposed to the component mounting space, the circumferential length element corresponding to a movement speed of the jig member in a radial direction, and wherein the support portions of the jig members are exposed to the component mounting space when the jig body is rotated in one direction, thereby enabling the jig device to be switched to a support mode in which the consumable component to be mounted is supported by the support portions, and the support portions of the jig members are inserted into an inner side of the jig body when the jig body is rotated in the other direction, thereby enabling the jig device to be switched to a mounting mode in which the consumable component to be mounted is mounted on and supported by the component mounting portion of the substrate processing device.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view showing a jig device according to an embodiment of the present disclosure;

FIG. 2 is an exploded perspective view of the jig device according to the embodiment of the present disclosure;

FIG. 3 is an enlarged view of a coupling portion of the jig device according to the embodiment of the present disclosure;

FIGS. 4 to 6 are views each showing a support mode operation of the jig device according to the embodiment of the present disclosure;

FIGS. 7 to 9 are views each showing a mounting mode operation of the jig device according to the embodiment of the present disclosure;

FIG. 10 is a flowchart of a focus ring mounting method using the jig device according to the embodiment of the present disclosure; and

FIGS. 11 to 19 are operation views of the focus ring mounting method according to the embodiment of the present disclosure.

### DETAILED DESCRIPTION OF EXEMPLARY EMBODIMENTS

Hereinafter, embodiments of the present disclosure will be described in detail with reference to the accompanying drawings. The present disclosure may, however, be embodied in many different forms, and should not be construed as being limited to the embodiments set forth herein.

Hereinafter, embodiments of the present disclosure will be described in detail with reference to the accompanying drawings in order to describe the present disclosure, the operational advantages thereof, and the purpose achieved by implementation of the present disclosure.

First, in the present disclosure, the terms used herein are only used to describe specific embodiments and are not intended to limit the present disclosure. In this specification, an expression in a singular form also encompasses the plural sense, unless clearly specified otherwise in context. Additionally, it should be understood that expressions such as "comprise" and "have" in this specification are intended to designate the presence of indicated features, numbers, steps, operations, components, parts, or combinations thereof, but do not exclude the presence or addition of one or more features, numbers, steps, operations, components, parts, or combinations thereof.

In describing the embodiments disclosed herein, when it is determined that a detailed description of related publicly known techniques may obscure the gist of the embodiments disclosed in this specification, the detailed description thereof will be omitted.

The present disclosure provides a jig device configured to align the position of a consumable component mounted on a substrate processing device and to support mounting of the consumable component on the substrate processing device.

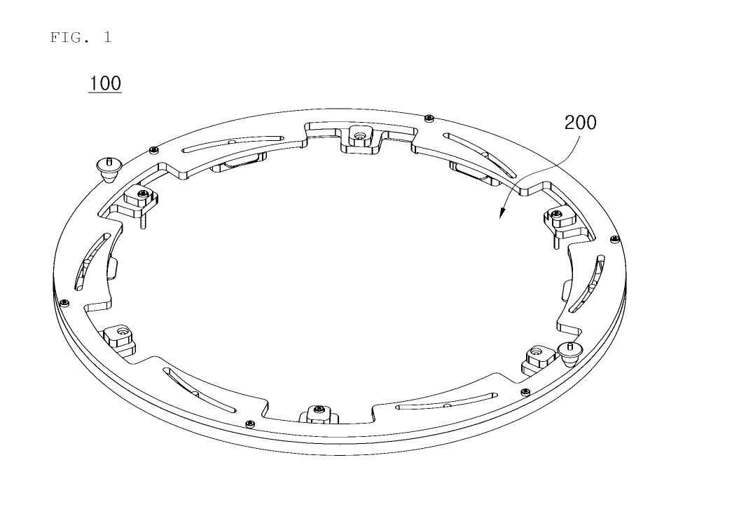

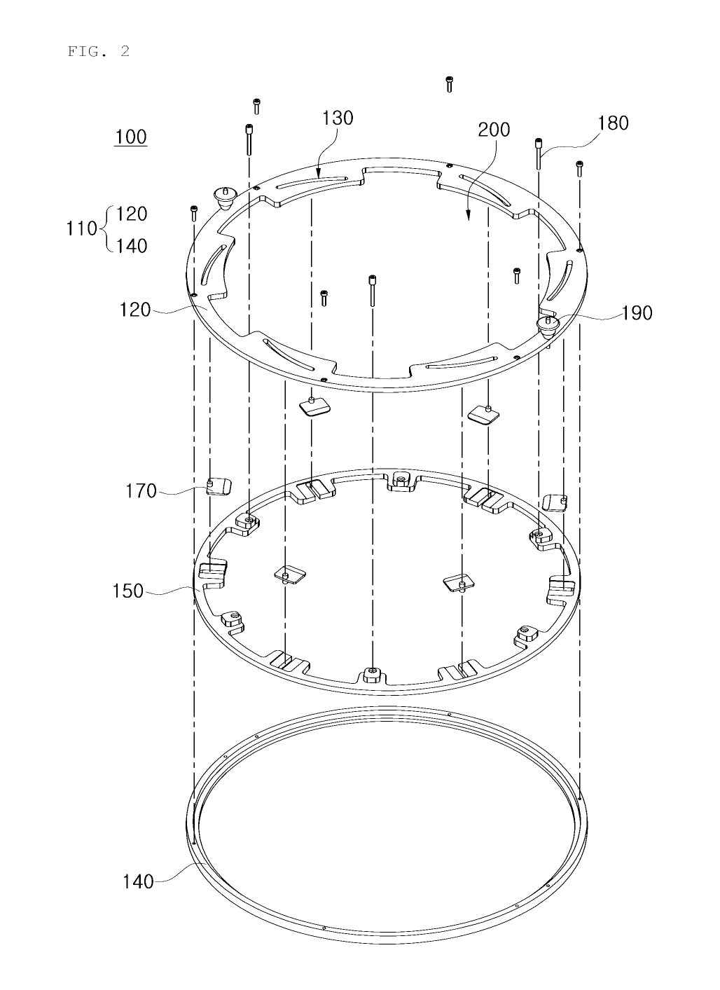

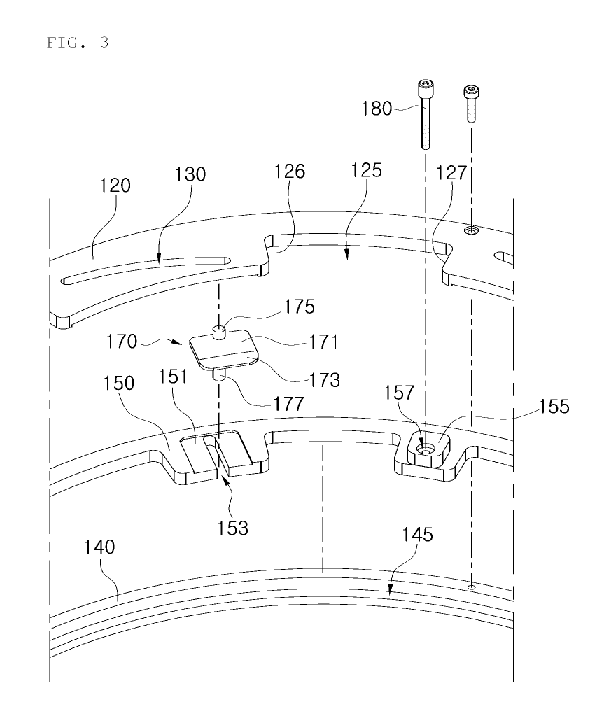

FIG. 1 is a view showing a jig device according to an embodiment of the present disclosure, FIG. 2 is an exploded perspective view of the jig device according to the embodiment of the present disclosure, and FIG. 3 is an enlarged view of a coupling portion of the jig device according to the embodiment of the present disclosure.

A jig device 100 may support mounting of a consumable component on a substrate processing device. The jig device 100 may support a consumable component to be mounted in a state in which the consumable component is spaced apart from a component mounting portion of the substrate processing device and may align the position of the consumable component to be mounted. Further, the jig device 100 may mount the consumable component at an accurate position by placing the aligned consumable component on the component mounting portion of the substrate processing device.

For example, the jig device 100 may mount a consumable component having an annular ring shape or a disc shape on the substrate processing device. To this end, a central portion of the jig device 100 may be formed to have a component mounting space 200 corresponding to the component mounting portion of the substrate processing device.

The jig device 100 may include a jig body 110, a jig plate 150, a jig member 170, and the like.

The jig body 110 has an annular shape and provides the component mounting space 200 in the central portion thereof.

The jig plate 150 is positioned inside the jig body 110 and is fixed to the substrate processing device on which the consumable component is mounted. The jig body 110 is rotatable in a state of being supported by the jig plate 150.

The jig member 170 is supported by the jig plate 150 and is partially exposed to the component mounting space 200 according to rotation of the jig body 110, thereby supporting the consumable components to be mounted.

The jig body 110 may have a mode switching track 130 provided therein. The mode switching track 130 may move the jig member 170 to selectively expose a part of the jig member 170 to the component mounting space 200 according to rotation of the jig body 110.

A plurality of mode switching tracks 130 may be arranged spaced apart from each other in the circumferential direction of the jig body 110. For example, a plurality of mode switching tracks 130 may be arranged spaced apart from each other with an equal interval therebetween in the circumferential direction.

A plurality of jig members 170 may be provided corresponding to the plurality of mode switching tracks 130 and may be arranged spaced apart from each other with an equal interval therebetween in the circumferential direction. For example, a plurality of jig members 170 may be arranged spaced apart from each other with an equal interval therebetween in the circumferential direction.

Each configuration of the jig device 100 will be described in more detail through the following embodiments.

The jig body 110 may be formed by coupling an upper cover 120 to a lower cover 140. The upper cover 120 and the lower cover 140 may be coupled to each other by fastening a screw member. In addition, the upper cover 120 and the lower cover 140 may be coupled to each other in various ways. For example, the upper cover 120 and the lower cover 140 may be coupled to each other using various fastening members such as a clamping member and a clip member or using an adhesive.

The upper cover 120 may be provided as an annular plate. The lower cover 140 may be provided as an annular ring or an annular plate having a stepped surface 145. For example, the upper cover 120 and the lower cover 140 may have the same outer diameter, and a width between the outer side and the inner side of the lower cover 140 may be smaller than a width between the outer side and the inner side of the upper cover 120.

When the lower cover 140 is coupled to the lower side of the upper cover 120, a jig plate mounting space in which the jig plate 150 is positioned may be provided through a step of the lower cover 140.

The upper cover 120 may be provided with a plurality of mode switching tracks 130 spaced apart from each other in the circumferential direction. For example, the plurality of mode switching tracks 130 may be arranged with an equal interval therebetween in the circumferential direction.

Each of the mode switching tracks 130 may be provided in the upper cover 120 in a diagonal direction of the circumferential direction. For example, the mode switching track 130 may be provided in the circumferential direction in a state in which one end of the mode switching track is adjacent to the outer diameter of the upper cover 120 and the other end thereof is adjacent to the inner diameter of the upper cover 120.

For example, the mode switching track 130 may be formed as a mode switching hole line passing through the upper cover 120. Alternatively, the mode switching track may be formed as a mode switching groove line recessed in the lower surface of the upper cover 120.

The length of the mode switching track 130 may be adjusted corresponding to the length of a support portion of the jig member 170 exposed to the component mounting space 200. The mode switching track 130 may be formed in an arc shape having a predetermined length. Alternatively, the mode switching track may be formed in a straight-line shape having a predetermined length. As will be described later, in order to secure stable movement of the jig member 170 according to rotation of the jig body 110, the mode switching track 130 is formed to have an arc shape.

The jig member 170 may be coupled to the mode switching track 130. The mode switching track 130 may move the jig member 170 according to rotation of the jig body 110.

For example, a mode switching protrusion 175 of the jig member 170 may be coupled to the mode switching track 130. The mode switching track 130 may move the mode switching protrusion 175 of the jig member 170 according to rotation of the jig body 110.

The upper cover 120 may have a damper space 125 provided therein. The damper space 125 may be provided by partially opening an inner diameter circumferential portion of the upper cover 120. The length of the damper space 125 may be formed corresponding to the length of the mode switching track 130.

A plurality of damper spaces 125 may be arranged spaced apart from each other in the inner diameter circumference of the upper cover 120. The mode switching tracks 130 and the damper spaces 125 may be alternately provided in the upper cover 120 in the circumferential direction.

The upper cover 120 may be provided with a handle 190. The handle 190 is fixedly mounted on the upper cover 120 to rotate the jig body 110 through external force applied to the handle 190.

The jig plate 150 may be provided as an annular plate. The jig plate 150 may be positioned in the jig plate mounting space provided in the jig body 110. The width of the jig plate 150 may be equal to or smaller than the width of the upper cover 120.

When a consumable component is mounted on the substrate processing device, the jig plate 150 may be fixed to the substrate processing device. In a state in which the jig plate 150 is fixed thereto, the jig body 110 may be rotated through the support of the jig plate 150.

The jig plate 150 may have a jig member mounting groove 151 formed therein and configured for the jig member 170 to be seated therein. The jig member mounting groove 151 may be formed to have a space corresponding to a lower cross-sectional area of the jig member 170. The jig member mounting groove 151 may extend in the radial direction and may be open toward the component mounting space 200. The jig member mounting groove 151 may guide movement of the jig member 170 in the radial direction.

The jig member mounting groove 151 may have a guide hole line 153 provided therein and formed to extend in the radial direction. A guide protrusion 177 of the jig member 170 may be coupled to the guide hole line 153. The guide hole line 153 may guide radial movement of the jig member 170 and may prevent separation of the jig member 170.

A damper block 155 may be provided on the jig plate 150. The damper block 155 may be located in the damper space 125 in the upper cover 120. A plurality of damper blocks 155 may be provided corresponding to the plurality of damper spaces 125 and may be arranged along the circumference of the jig plate 150. During rotational movement of the jig body 110, the damper blocks 155 may contact partition walls 126 and 127 on opposite sides of the damper space 125 such that a rotation angle of the jig body 110 is limited.

A tab coupling portion 157 may be provided in the damper block 155. The tab coupling portion 157 may be provided in all of the damper blocks 155 or may be provided in one or more selected damper blocks 155.

The tab coupling portion 157 may be provided as a through hole. A fixing tab 180 may be inserted through the tab coupling portion 157. The fixing tab 180 may be coupled to the substrate processing device by passing through the tab coupling portion 157. The jig plate 150 may be fixed to the substrate processing device through the fixing tab 180.

The plurality of jig member mounting grooves 151 and the plurality of damper blocks 155 may be alternately arranged along the jig plate 150.

The jig member 170 may include a jig block 171, the mode switching protrusion 175, the guide protrusion 177, and the like.

The jig block 171 may be mounted in the jig member mounting groove 151 in the jig plate 150. The jig block 171 may be radially movable along the jig member mounting groove 151.

One end portion of the upper surface of the jig block 171 may function as a support portion to support a consumable component. The support portion may include an inclined seating guide surface 173. The seating guide surface 173 may guide, through the inclined surface thereof, seating of a consumable component to be mounted on the component mounting portion of the substrate processing device.

The upwardly protruding mode switching protrusion 175 may be provided on the upper surface of the jig block 171. The mode switching protrusion 175 may be inserted into and coupled to the mode switching track 130 provided in the upper cover 120. The mode switching protrusion 175 may move the jig block 171 in the radial direction while moving along the mode switching track 130.

The guide protrusion 177 protruding downwards may be provided on the lower surface of the jig block 171. The guide protrusion 177 may be inserted into and coupled to the guide hole line 153 provided in the jig member mounting groove 151. The guide protrusion 177 guides radial movement of the jig block 171 and prevents separation of the jig block 171.

In the present disclosure, the jig device 100 may be selectively switched between a support mode and a mounting mode.

In the support mode, the jig device 100 may support alignment of the consumable component while supporting the consumable component located in the component mounting space 200 in a state in which the consumable component is spaced apart from the component mounting portion of the substrate processing device. In addition, in the mounting mode, the jig device 100 may support mounting of the consumable component by stably placing the aligned consumable component on the component mounting portion of the substrate processing device.

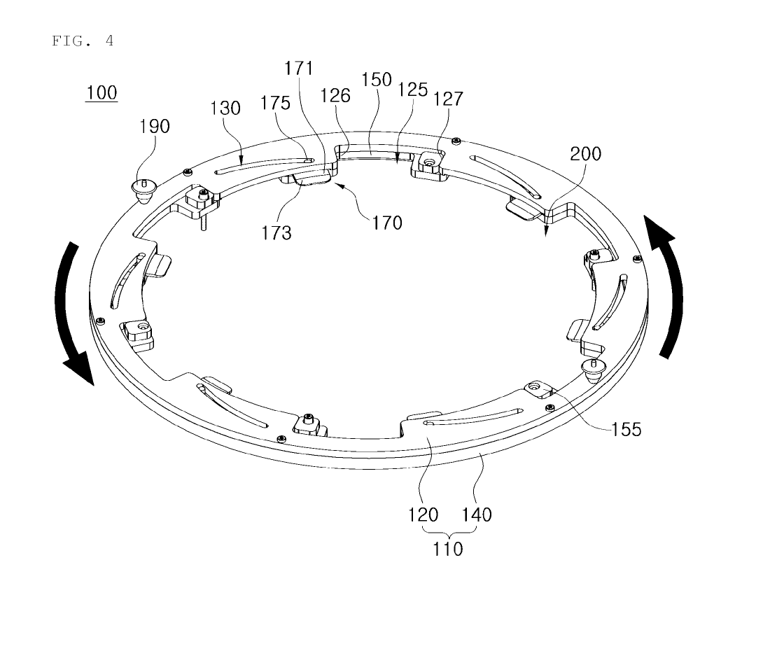

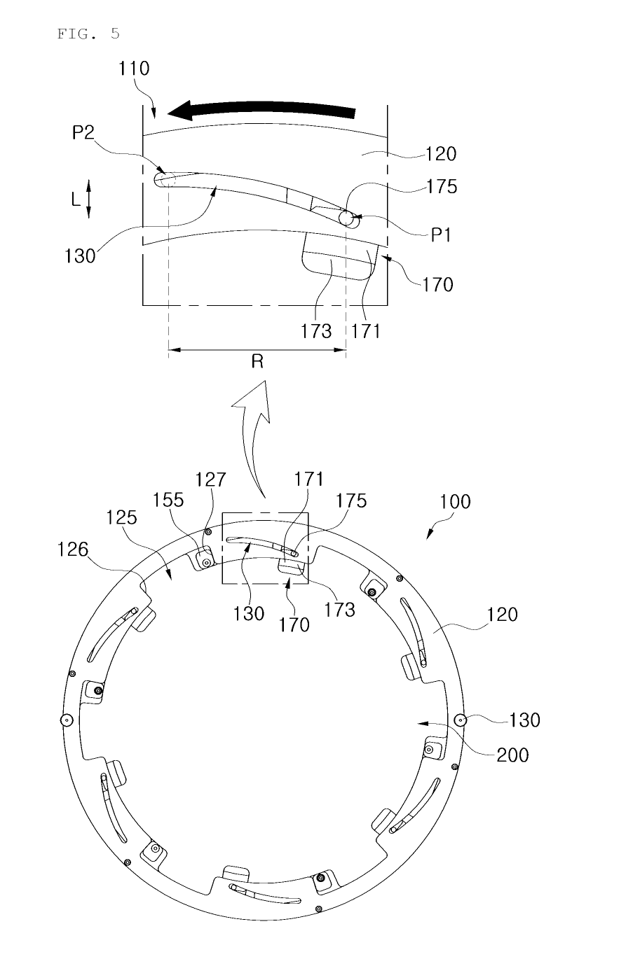

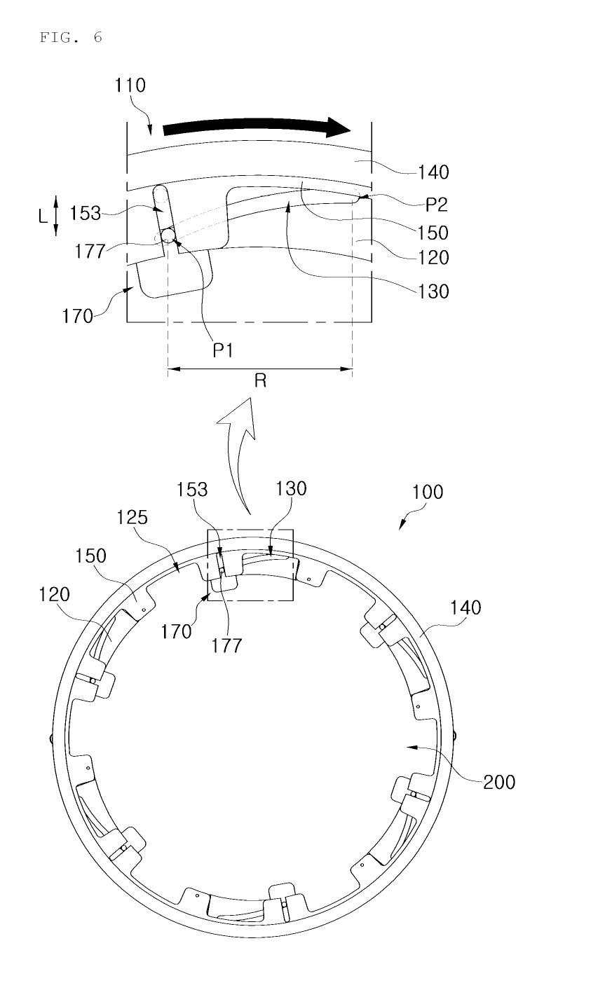

FIGS. 4 to 6 are views each showing a support mode operation of the jig device according to the embodiment of the present disclosure. FIG. 4 is a view showing an operation of switching the mode of the jig device 100 to the support mode, FIG. 5 shows the jig device 100 in the support mode when viewed from above, and FIG. 6 shows the jig device 100 in the support mode when viewed from below.

The mode of the jig device 100 may be switched to the support mode by rotating the jig body 110 counterclockwise using the handle 190.

The mode switching track 130 may be divided into a radial length element and a circumferential length element. In the present embodiment, the circumferential length element of the mode switching track 130 may be defined as a length R, and the radial length element of the mode switching track 130 may be defined as a length L.

The damper space 125 is formed to have a length corresponding to the circumferential length element R of the mode switching track 130. When the jig body 110 is rotated counterclockwise, the damper block 155 provided on the jig plate 150 contacts the right-side partition wall 127 of the damper space 125. In a state in which the jig plate 150 is fixed, further rotation of the jig body 110 may be limited by the damper block 155.

Here, circumferential movement of the jig member 170 may be limited by the jig member mounting groove 151 and the guide hole line 153 in the jig plate 150. On the other hand, radial movement of the jig member 170 may be guided by the jig member mounting groove 151 and the guide hole line 153.

Accordingly, the jig member 170 may be moved by the mode switching track 130 according to counterclockwise rotation of the jig body 110. The jig member 170 may be radially moved toward the component mounting space 200 according to guidance of the jig member mounting groove 151 and the guide hole line 153.

More specifically, when the upper cover 120 is rotated counterclockwise relative to the length R of the circumferential length element, the mode switching protrusion 175 may be moved from a point P2 to a point P1 in the mode switching track 130. However, the jig member 170 may actually be moved only in the radial direction in a state of being supported by the jig plate 150. That is, the jig member 170 may be moved in the radial direction toward the component mounting space 200 by the length L of the radial length element of the mode switching track 130, and the support portion of the jig member 170 may be exposed to the component mounting space 200.

In the support mode, the support portion of the jig member 170 is exposed to the component mounting space 200, thereby enabling the consumable component to be supported by the support portion of the jig member 170.

Furthermore, the position of the consumable component may be easily adjusted in a state in which the consumable component is supported by the jig device 100 and is spaced apart from the component mounting portion of the substrate processing device by a predetermined distance.

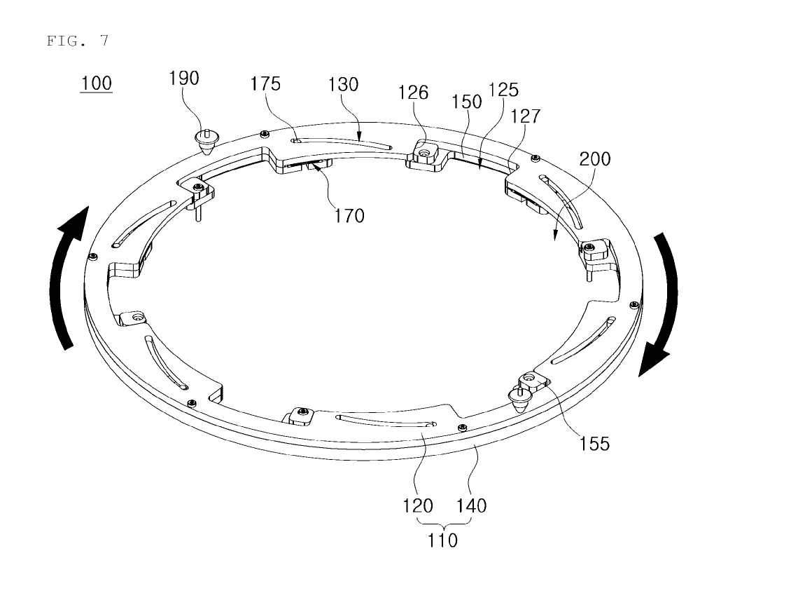

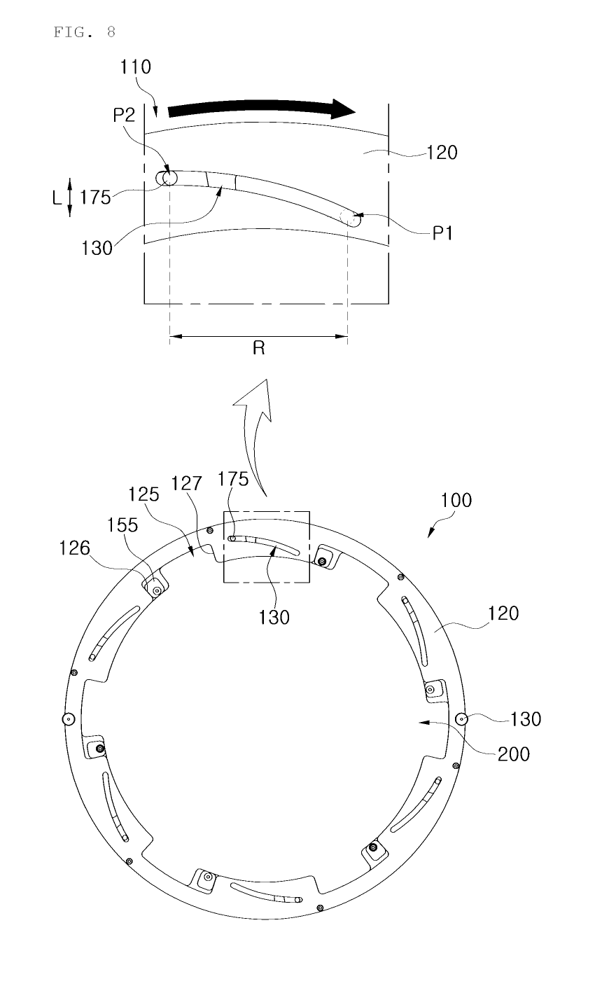

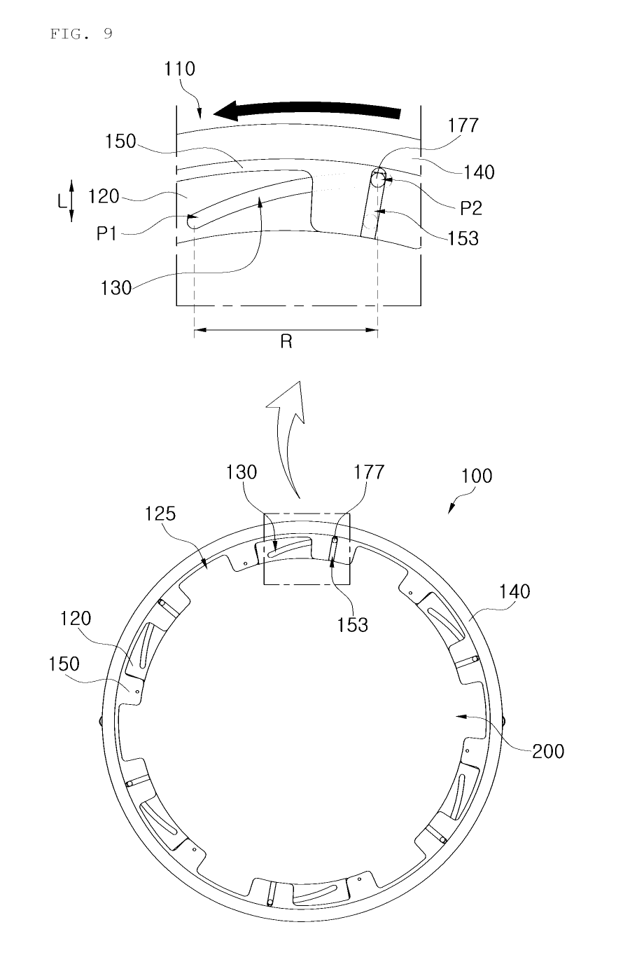

FIGS. 7 to 9 are views each showing a mounting mode operation of the jig device according to the embodiment of the present disclosure. FIG. 7 is a view showing an operation of switching the mode of the jig device 100 to the mounting mode, FIG. 8 is a view showing the jig device 100 in the mounting mode when viewed from above, and FIG. 9 is a view showing the jig device 100 in the mounting mode when viewed from below.

When the jig body 110 in the support mode is rotated clockwise using the handle 190, the mode of the jig device 100 may be switched to the mounting mode.

When the jig body 110 is rotated clockwise, the damper block 155 provided on the jig plate 150 contacts the left-side partition wall 126 in the damper space 125. In a state in which the jig plate 150 is fixed, further rotation of the jig body 110 may be limited by the damper block 155.

Here, circumferential movement of the jig member 170 may be limited by the jig member mounting groove 151 and the guide hole line 153 in the jig plate 150. On the other hand, radial movement of the jig member 170 may be guided by the jig member mounting groove 151 and the guide hole line 153.

Therefore, when the jig body 110 is rotated clockwise, the jig member 170 is moved by the mode switching track 130, and the jig member 170 may be radially moved toward the inside of the jig body 110 according to guidance of the jig member mounting groove 151 and the guide hole line 153.

More specifically, when the upper cover 120 is rotated clockwise corresponding to the length R of the circumferential length element, the mode switching protrusion 175 may be moved from the point P1 to the point P2 in the mode switching track 130. However, since the jig member 170 is actually moved only in the radial direction, the jig member 170 may be radially moved toward the inside of the jig body 110 by the length L of the radial length element. Accordingly, the support portion of the jig member 170 may be inserted into the jig body 110.

When the support mode is switched to the mounting mode, the support portion of the jig member 170, exposed to the component mounting space 200, is inserted into the jig body 110, and the consumable component is not supported by the support portion of the jig member 170. When the mode of the jig device 100 is switched to mounting mode, the consumable component may be seated and mounted on the component mounting portion of the substrate processing device.

Furthermore, the movement speed of the jig member 170 may vary depending on the length R of the circumferential length element. That is, when the length R of the circumferential length element is increased in a state in which the length L of the radial length element is fixed, the movement speed of the mode switching protrusion 175 in the radial direction becomes slower. Conversely, when the length R of the circumferential length element is reduced in a state in which the length L of the radial length element is fixed, the movement speed of the mode switching protrusion 175 in the radial direction becomes faster.

Therefore, the movement speed of the jig member 170 may be controlled by adjusting the circumferential length element of the mode switching track 130. Accordingly, the consumable component may be more stably seated on the component mounting portion of the substrate processing device.

In the above embodiment, a description has been given as to a case in which the mode of the jig device 100 switched to the support mode when the jig body 110 is rotated counterclockwise, and the mode of the jig device 100 is switched to the mounting mode when the jig body 110 is rotated clockwise. However, the rotation direction for mode switching may be reversed depending on the shape and direction of the mode switching track 130.

As described above, the jig device according to the present disclosure aligns the position of the consumable component having an annular ring shape or a disc shape, thereby enabling the consumable component to be stably and accurately mounted on the substrate processing device.

The present disclosure proposes a focus ring mounting method using the jig device. Hereinafter, the focus ring mounting method using the jig device according to the present disclosure will be described with reference to an embodiment.

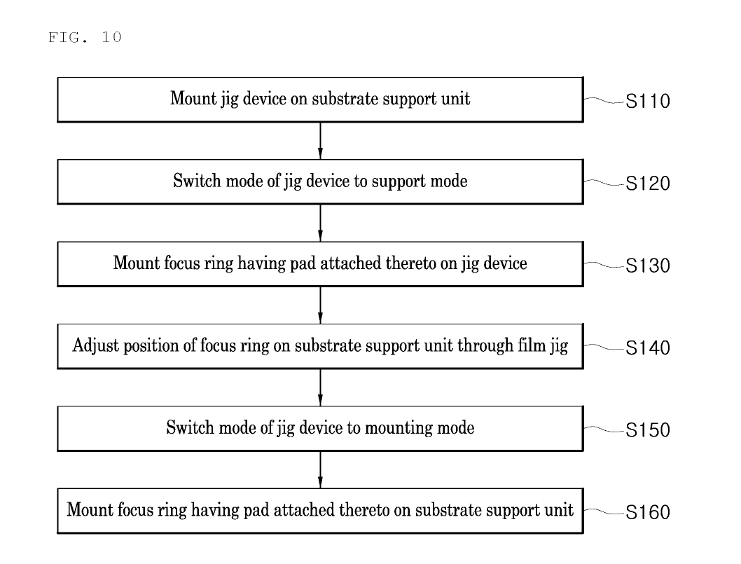

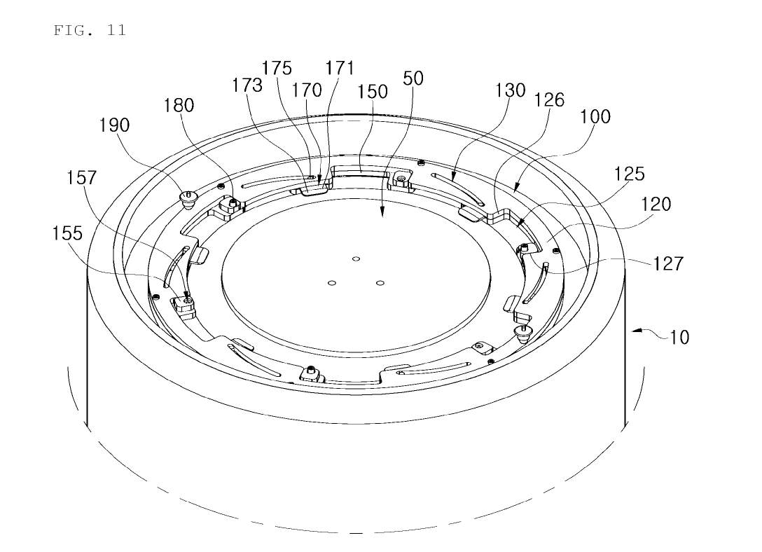

FIG. 10 is a flowchart of the focus ring mounting method using the jig device according to the embodiment of the present disclosure, and FIGS. 11 to 19 are operation views of the focus ring mounting method according to the embodiment of the present disclosure.

To mount a focus ring F on a substrate support unit 50 on a substrate processing device 10, the jig device 100 may be mounted on the substrate support unit 50 (S110).

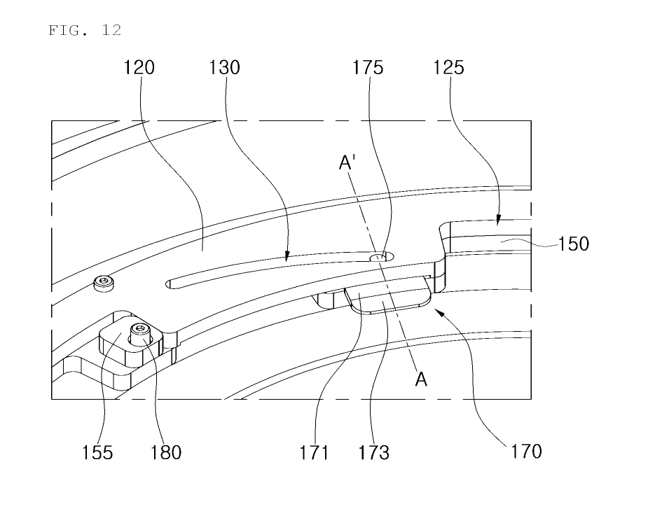

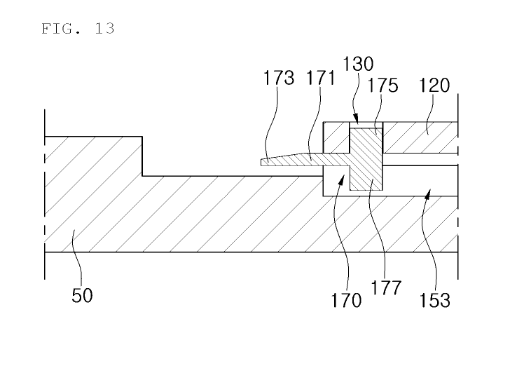

FIGS. 11 to 13 are views each showing the operation of the jig device 100 in the support mode. FIG. 11 is a view showing an example of the jig device 100 in the support mode mounted on the substrate processing device 10, FIG. 12 is an enlarged view of a part of the jig device 100 in FIG. 11, and FIG. 13 is a cross-sectional view taken along line A-A' in FIG. 11.

The jig device 100 may be mounted on the substrate support unit 50 through the fixing tab 180 in a state in which the jig device 100 is aligned with a focus ring mounting portion on the substrate support unit 50. For example, a fixing tab coupling hole may be provided in the substrate support unit 50, and the jig device 100 may be mounted on the substrate support unit 50 by coupling the fixing tab 180 to the fixing tab coupling hole in the substrate support unit 50 in a state in which the jig device 100 is aligned with and seated on the substrate support unit 50.

When the jig device 100 is mounted on the substrate support unit 50, the jig plate 150 may be fixed to the substrate support unit 50 by the fixing tab 180.

When external force is applied counterclockwise to the handle 190 of the jig device 100, the jig body 110 including the upper cover 120 may be rotated counterclockwise while being supported by the jig plate 150. The mode of the jig device 100 may be switched to the support mode (S120) according to counterclockwise rotation of the jig body 110.

More specifically, as the mode switching protrusion 175 of the jig member 170 is moved through the mode switching track 130 according to counterclockwise rotation of the jig body 110. In this case, the jig member 170 may be radially moved corresponding to the radial length element of the mode switching track 130. Here, the damper block 155 contacts the right-side partition wall 127 of the damper space 125 such that the rotation angle of the jig body 110 is limited corresponding to the circumferential length element of the mode switching track 130.

According to radial movement of the jig member 170, the support portion of the jig member 170 may be exposed to the component mounting space.

Here, a plurality of jig members 170 may be simultaneously moved along the circumference of the upper cover 120 by a plurality of mode switching tracks 130 provided in the upper cover 120. Accordingly, the support portions of the plurality of jig members 170 may be simultaneously exposed with an equal interval therebetween along the circumference of the upper cover 120 in a state in which the support portions are located above the focus ring mounting portion on the substrate support unit 50.

In a state in which the jig device 100 is in the support mode, the focus ring F having an adhesive pad P attached thereto may be mounted on the jig device 100 (S130).

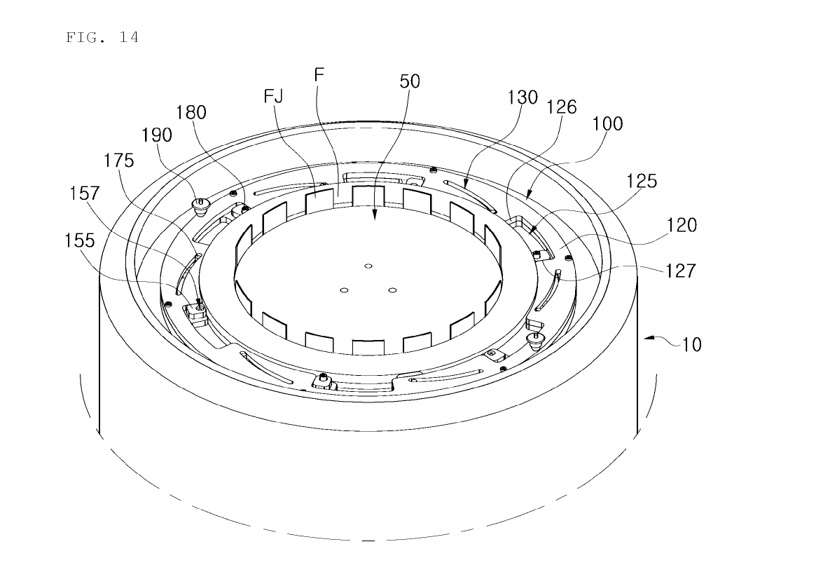

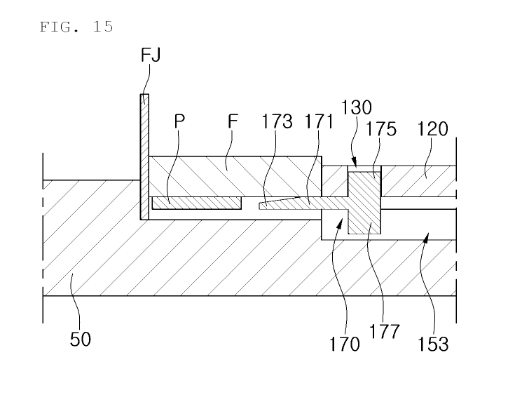

FIG. 14 is a view showing an example of the focus ring F seated on the jig device 100 in the support mode, and FIG. 15 is a cross-sectional view of a part of FIG. 14.

The jig device 100 may support the focus ring F having the adhesive pad P attached thereto.

The focus ring F may be seated on and supported by the support portion of the jig member 170. The support portion of the jig member 170 may support the focus ring F in a state in which the focus ring F is spaced apart from the focus ring mounting portion of the substrate support unit 50 by a predetermined distance. For example, the support portion of the jig member 170 may support an outer portion of the focus ring F. Here, the adhesive pad P is not attached to the outer portion. Accordingly, the adhesive pad P attached to the focus ring F may be kept spaced apart from an upper portion of the substrate support unit 50 without contacting the focus ring mounting portion of the substrate support unit 50.

While the target focus ring F is mounted on the jig device 100, a film jig FJ (i.e., a gap adjustment film) may be inserted between the side surface of the substrate support unit 50 and the side surface of the focus ring F to adjust a separation distance therebetween. The separation distance between the substrate support unit 50 and the focus ring F may be adjusted by the film jig FJ.

Since the adhesive pad P attached to the focus ring F is not in contact with the focus ring mounting portion of the substrate support unit 50, the central position of the focus ring F may be easily adjusted through the film jig FJ (S140).

In a state in which the focus ring F is aligned with the focus ring mounting portion of the substrate support unit 50 such that the central position of the focus ring F is adjusted, the mode of the jig device 100 may be switched to the mounting mode (S150).

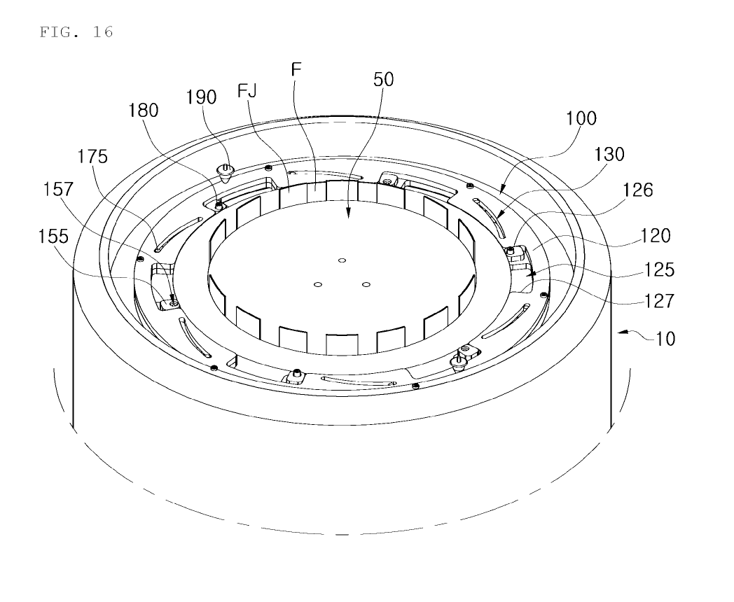

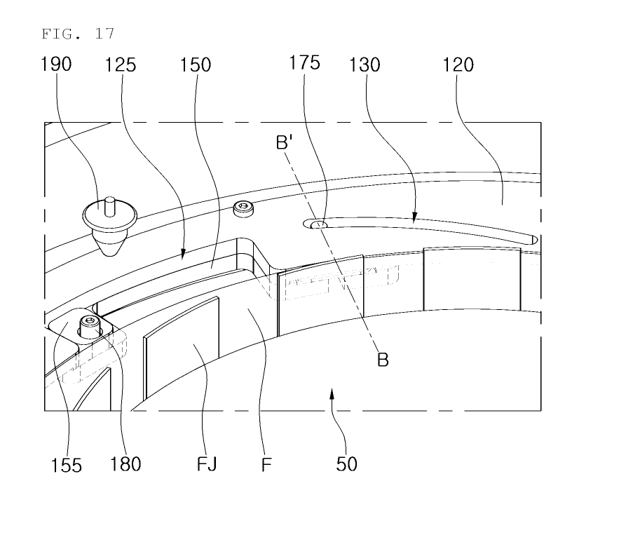

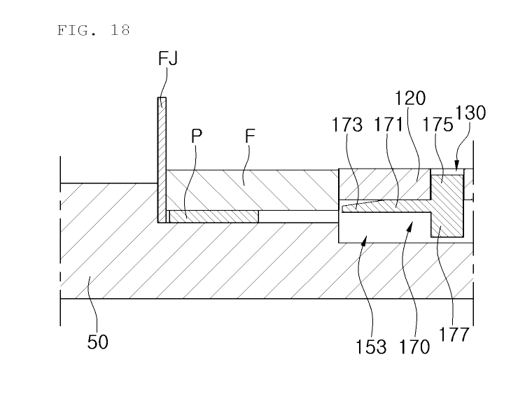

FIGS. 16 to 18 are views showing the mounting mode operation of the jig device 100. FIG. 16 is a view showing an example of the jig device 100 in the mounting mode mounted on the substrate processing device 10, FIG. 17 is an enlarged view of a part of the jig device 100 in FIG. 16, and FIG. 18 is a cross-sectional view taken along line B-B' in FIG. 17.

When external force is applied clockwise to the handle 190 of the jig device 100 in a state in which the central position of the focus ring F is aligned with the focus ring mounting portion of the substrate support unit 50, the jig body 110 including the upper cover 120 may be rotated clockwise while being supported by the jig plate 150. According to clockwise rotation of the jig body 110, the mode of the jig device 100 may be switched to the mounting mode (S150).

More specifically, as the mode switching protrusion 175 of the jig member 170 is moved through the mode switching track 130 according to clockwise rotation of the jig body 110, the jig member 170 may be radially moved corresponding to the radial length element of the mode switching track 130. A plurality of jig members 170 may be simultaneously inserted into the jig body 110 while being radially moved. In this case, the damper block 155 contacts the left-side partition wall 126 of the damper space 125 such that the rotation angle of the jig body 110 is limited corresponding to the circumferential length element of the mode switching track 130.

When the jig member 170 is gradually inserted into the jig body 110, the focus ring F having the adhesive pad P attached thereto may be mounted on the focus ring mounting portion of the substrate support unit 50 (S160).

In an embodiment, the end of the support portion of the jig block 171 supporting the focus ring F is provided with the inclined seating guide surface 173. Then, the focus ring F is gradually moved downwards along the seating guide surface 173, thereby allowing the adhesive pad P to contact the focus ring mounting portion of the substrate support unit 50.

Furthermore, the radial movement speed of the jig member 170 may be adjusted according to the radial length element of the mode switching track 130. Thus, the focus ring F may be stably mounted on the focus ring mounting portion of the substrate support unit 50 without shaking.

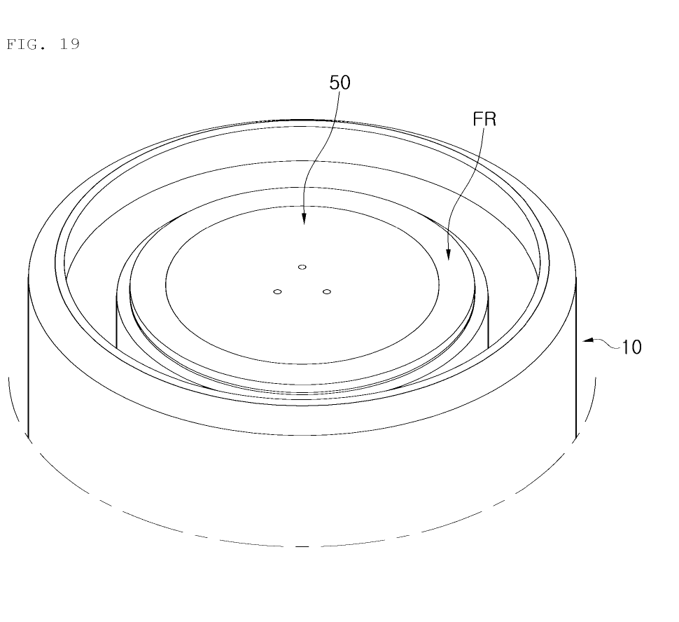

After the focus ring F is mounted on the substrate support unit 50 in a state in which the central position of the focus ring F is aligned, the film jig FJ may be removed. Then, the fixing tab 180 of the jig device 100 is released, and the jig device 100 is removed. In this manner, mounting of the focus ring F may be completed in a state in which the central position of the focus ring F is aligned on the substrate support unit 50, as shown in FIG. 19.

In this manner, according to the present disclosure, the central position of a focus ring may be easily adjusted by a jig device in a state in which an adhesive pad is attached to the focus ring, and the focus ring may be mounted at an accurate position on a substrate support unit.

As is apparent from the above description, according to the embodiment of the present disclosure, the position of a consumable component having an annular ring shape or a disc shape may be aligned, thereby enabling the consumable component to be stably and accurately mounted on a substrate processing device.

Particularly, the central position of a focus ring may be easily adjusted using a jig device in a state in which an adhesive pad is attached to the focus ring, thereby enabling the focus ring to be mounted at an accurate position on a substrate support unit.

The movement speed of a jig member is controlled by adjusting a circumferential length element of a mode switching track of the jig device, thereby enabling the consumable component to be mounted on a component mounting portion of the substrate processing device more accurately without shaking.

The effects of the present disclosure are not limited to the above-mentioned effects, and other effects not mentioned herein will be clearly understood by those skilled in the art to which the present disclosure pertains from the detailed description of the embodiments.

Although the embodiments of the present disclosure have been disclosed for illustrative purposes, those skilled in the art will appreciate that various modifications, additions, and substitutions are possible, without departing from the scope and spirit of the disclosure. Therefore, the embodiments described in the present disclosure are not intended to limit the technical idea of the present disclosure, and the technical idea of the present disclosure is not limited by the embodiments. The protection scope of the present disclosure should be interpreted by the following claims, and all technical ideas within the scope equivalent thereto should be construed as being included in the scope of the present disclosure.

What is claimed is:

1. A jig device comprising:
a jig plate fixed to a substrate processing device configured for a consumable component to be mounted thereon;
a jig body having an annular shape and providing a component mounting space corresponding to a component mounting portion of the substrate processing device, the jig body being rotatable in a state of being supported by the jig plate; and
a jig member supported by the jig plate, wherein the jig member is moved by rotation of the jig body such that a support portion of the jig member is exposed to the component mounting space to support the consumable component to be mounted.

2. The jig device as claimed in claim 1,
wherein the jig body has a mode switching track provided therein and configured to, based on the rotation of the jig body, move the jig member so as to allow the support portion of the jig member to be selectively exposed to the component mounting space,
wherein the jig device comprises a plurality of mode switching tracks including the mode switching track,
wherein plurality of mode switching tracks are spaced apart from each other with an equal interval therebetween in a circumferential direction of the jig body,
wherein the jig device further comprises a plurality of jig members including the jig member, and
wherein the plurality of jig members are spaced apart from each other with an equal interval therebetween in the circumferential direction.

3. The jig device as claimed in claim 2,
wherein the plurality of support portions of the plurality of jig members are simultaneously exposed to the component mounting space when the jig body is rotated in one direction, thereby enabling the jig device to be switched to a support mode in which the consumable component to be mounted is supported by the plurality of support portions, and
wherein the plurality of support portions of the plurality of jig members are simultaneously inserted into an inner side of the jig body when the jig body is rotated in the other direction, thereby enabling the jig device to be switched to a mounting mode in which the consumable component to be mounted is mounted on and supported by the component mounting portion of the substrate processing device.

4. The jig device as claimed in claim 2,
wherein the jig body comprises:
an upper cover having the plurality of mode switching tracks provided therein and spaced apart from each other in the circumferential direction; and
a lower cover coupled to a lower portion of the upper cover, the lower cover providing a jig plate mounting space configured for the jig plate to be positioned therein.

5. The jig device as claimed in claim 4,
wherein each of the plurality of mode switching tracks comprises a mode switching hole line or a mode switching groove line, the mode switching hole line being formed to pass through the upper cover in a diagonal direction of the circumferential direction of the upper cover, the mode switching groove line being formed to be recessed in the upper cover, and
wherein the jig member comprises a mode switching protrusion coupled to the mode switching track and configured to be moved along the mode switching track.

6. The jig device as claimed in claim 5,
wherein a length of the mode switching track is divided into a radial length element and a circumferential length element, wherein the radial length element corresponds to a length of the support portion of the jig member exposed to the component mounting space, and wherein the circumferential length element affects a movement speed of the jig member in a radial direction.

7. The jig device as claimed in claim 6,
wherein the jig body comprises a damper space formed to be open by a length corresponding to the circumferential length element of the mode switching track, and
wherein the jig plate comprises a damper block positioned in the damper space, the damper block being configured to, based on the rotation of the jig body, contact partition walls on opposite sides of the damper space to limit a rotation angle of the jig body.

8. The jig device as claimed in claim 7,
wherein the jig body has the mode switching tracks and the damper spaces provided therein and alternately arranged in the circumferential direction.

9. The jig device as claimed in claim 1,
wherein the jig plate comprises a jig member mounting groove configured for the jig member to be mounted thereon, the jig member mounting groove being configured to, based on movement of the jig member by the rotation of the jig body, guide radial movement of the jig member.

10. The jig device as claimed in claim 9,
wherein the jig member further comprises a guide protrusion protruding downwards, and
wherein the jig plate further comprises a guide line radially formed as a guide groove line or a guide hole line in the jig member mounting groove and configured for the guide protrusion to be coupled thereto, the guide line being configured to guide the radial movement of the jig member and to prevent separation of the jig member.

11. The jig device as claimed in claim 1,
wherein the jig member comprises a seating guide surface formed to be inclined at an end portion of the support portion to guide seating of the consumable component to be mounted on the component mounting portion of the substrate processing device.

12. The jig device as claimed in claim 1, further comprising a fixing tab coupled to the substrate processing device to fix the jig plate,
wherein the jig plate comprises a tab coupling portion configured for the fixing tab to be coupled thereto.

13. The jig device as claimed in claim 1, further comprising a handle connected to the jig body and configured to rotate the jig body through external force applied to the handle.

14. A method of mounting a focus ring using a jig device, the method comprising:
a support mode switching step of exposing a jig member of the jig device mounted on a substrate support unit to a component mounting space according to rotation of a jig body in one direction;
a focus ring support step of spacing, by the jig member, a focus ring having an adhesive pad attached thereto from a focus ring mounting portion of the substrate support unit and supporting, by the jig member, the focus ring in the component mounting space;
a focus ring position adjustment step of adjusting a position of the focus ring in a state in which the jig member supports the focus ring; and
a mounting mode switching step of releasing, based on the jig member being gradually inserted into an inner side of the jig body according to rotation of the jig body in the other direction, support of the jig member for the focus ring, and then allowing the focus ring to be seated on the focus ring mounting portion of the substrate support unit.

15. The jig device as claimed in claim 14,
wherein the support mode switching step comprises radially moving, based on rotation of the jig body in one direction in a state in which the jig body is supported by a jig plate of the jig device fixed to the substrate support unit, the jig member by a radial length element of a mode switching track provided in the jig body, and then allowing a support portion of the jig member to be exposed to the component mounting space.

16. The jig device as claimed in claim 14,
wherein the focus ring support step comprises supporting, by a support portion of the jig member, an outer portion of the focus ring, wherein the adhesive pad is not attached to the outer portion.

17. The jig device as claimed in claim 14,
wherein the focus ring position adjustment step comprises adjusting, by a gap adjustment film, the position of the focus ring, the gap adjustment film being inserted between a side surface of the focus ring and a side surface of the substrate support unit.

18. The jig device as claimed in claim 14,
wherein the mounting mode switching step comprises radially moving, based on the rotation of the jig body in the other direction in a state in which the jig body is supported by a jig plate of the jig device fixed to the substrate support unit, the jig member by a radial length element of a mode switching track provided in the jig body, and then allowing the jig member to be gradually inserted into the inner side of the jig body.

19. The jig device as claimed in claim 18,
wherein the mounting mode switching step comprises a radial movement speed of the jig member being controlled by a circumferential length element of the mode switching track provided in the jig body.

20. A jig device comprising:
a jig plate fixed to a substrate processing device configured for a consumable component to be mounted thereon;
a jig body having an annular shape and providing a component mounting space corresponding to a component mounting portion of the substrate processing device, the jig body comprising an upper cover and a lower cover, the upper cover having a plurality of mode switching tracks provided therein and spaced apart from each other in a circumferential direction, the lower cover coupled to a lower portion of the upper cover and configured to provide a jig plate mounting space configured for the jig plate to be positioned therein, the jig body being rotatable in a state of being supported by the jig plate; and
a plurality of jig members supported by the jig plate, each of the plurality of jig members comprising a mode switching protrusion coupled to a corresponding one of the plurality of mode switching tracks, wherein the plurality of jig members are moved by rotation of the jig body such that support portions of the plurality of jig members are exposed to the component mounting space to support the consumable component to be mounted, and wherein the plurality of jig members are provided corresponding to the plurality of mode switching tracks,
wherein each of the plurality of mode switching tracks comprises a mode switching hole line or a mode switching groove line, the mode switching hole line being formed to pass through the upper cover in a diagonal direction of the circumferential direction of the upper cover, the mode switching groove line being formed to be recessed in the upper cover, and is configured to, based on the rotation of the jig body, move a corresponding one of the plurality of jig members so as to allow a support portion of the corresponding one of the plurality of jig members to be selectively exposed to the component mounting space,
wherein a length of each of the plurality of mode switching tracks is divided into a radial length element and a circumferential length element, the radial length corresponding to a length of the support portion of the corresponding one of the plurality of jig members exposed to the component mounting space, the circumferential length corresponding to a movement speed of the corresponding one of the plurality of jig members in a radial direction, and
wherein the support portions of the plurality of jig members are exposed to the component mounting space when the jig body is rotated in one direction, thereby enabling the jig device to be switched to a support mode in which the consumable component to be mounted is supported by the support portions, and the support portions of the plurality of jig members are inserted into an inner side of the jig body when the jig body is rotated in the other direction, thereby enabling the jig device to be switched to a mounting mode in which the consumable component to be mounted is mounted on and supported by the component mounting portion of the substrate processing device.
